(19) United States
(12) Patent Application Publication
(10) Pub. No.: US 2005/0100828 A1
(43) Pub. Date: May 12, 2005

(54) Mass production method for three-dimensional micro structure having high aspect ratio

(76) Inventors: Jong Won Kim, Seoul (KR); Hyun Se Kim, Seoul (KR); Ki Baik Kwon, Donghae-si (KR); Chan Yoon, Seoul (KR); Tae-Won Seo, Geoje-si (KR)

Correspondence Address: Thomas J. D'Amico;Dickstein, Shapiro, Morin & Oshinsky L.L.P., 2101 L Street NW, Washington, DC, 20037-1526, US

(21) Appl. No.: 10/782,778

(22) Filed: Feb. 23, 2004

(30) Foreign Application Priority Data
Nov. 6, 2003 (KR) 10-2003-0078423

(51) Int. Cl. G03F 7/00

(52) U.S. Cl. 430/314; 430/312; 430/313

(57) ABSTRACT

The present invention relates to mass production method for three-dimensional micro structure and especially to the mass production method for three-dimensional metal micro structure having high aspect ratio. According to the present invention, the manufacturing of the three-dimensional micro structure having high aspect ratio is possible, which was impossible with the prior art of MEMS or LIGA. Especially, micro structure with complex shape can be obtained through dividing into layers and depositing the layers. Micro structure with any shape can be obtained with the method according to the present invention.

### BACKGROUND OF THE INVENTION

1. Field of the Invention

The present invention relates to mass production method for three-dimensional micro structure and especially to the mass production method for three-dimensional metal micro structure having high aspect ratio.

2. Background of the Related Art

Traditionally, the mass production of micro structure was performed through the MEMS (Micro Electro Mechanical System) process, which is based on silicon. MEMS process uses single crystal silicon, which is transformed to micro structure through the repeated processes of dry etching, wet etching, photolithography, sputtering, plating and etc. But, the traditional method has a shortcoming that the only available material for MEMS process is silicon.

Another traditional mass production method is LIGA (Lithograpie Galvanofomung Abformung). LIGA is the process to use micro mold for mass production, which was obtained through etching end plating processes.

LIGA can use various kinds of materials such as silicon, ceramic, polymer, metal alloy and etc. But, it can't be applied in cases when the products have inclined plane or the cross sectional area of the upper part is larger than that of the lower part. Also, it is not suitable for the products with three-dimensional high aspect ratio micro structure.

That is, the traditional method have limits in aspect ratio: MEMS process can produce the products with maximum aspect ratio of 30:1, and the LIGA can produce with maximum aspect ratio of 50:1.

With the production of various kinds of micro devices, the demands for the materials with excellent properties such as strength, heat transfer property and etc. are increasing. Especially, in case of micro refrigerator, silicon has a limit in heat transfer property for being used in the condenser or evaporator that require active heat transfer.

Accordingly, the need for the mass production method of three-dimensional micro structure having high aspect ratio, which uses material with excellent heat transfer property, has been on the rise. The present invention was developed to solve above-mentioned problems. The present invention is to provide mass production method for three-dimensional metal micro structure having high aspect ratio, which is suitable for mass production and uses metal having excellent heat transfer property.

### SUMMARY OF THE INVENTION

The present invention relates to mass production method for three-dimensional micro structure and especially to the mass production method for three-dimensional metal micro structure having high aspect ratio.

According to the present invention, the manufacturing of the three-dimensional micro structure having high aspect ratio is possible, which was impossible with the prior art of MEMS or LIGA. Especially, micro structure with complex shape can be obtained through dividing into layers and depositing the layers. Micro structure with any shape can be obtained with the method according to the present invention.

### BRIEF DESCRIPTION OF THE DRAWINGS

FIG. 1 is a drawing showing the partial perspective view of the macro channel.

FIG. 2 is a drawing showing the seed layer forming process, where the seed layer is formed on silicon substrate for the manufacturing of micro channel according to the present invention.

FIG. 3 is a drawing illustrating the ensuing process, which follows the process illustrated in FIG. 2.

FIG. 4 is a drawing illustrating the ensuing process, which follows the process illustrated in FIG. 3.

FIG. 5 is a drawing illustrating the ensuing process, which follows the process illustrated in FIG. 4.

FIG. 6 is a drawing illustrating the ensuing process, which follows the process illustrated in FIG. 5.

FIG. 7 is a drawing illustrating the ensuing process, which follows the process illustrated in FIG. 6.

FIG. 8 is a drawing illustrating the ensuing process, which follows the process illustrated in FIG. 7.

FIG. 9 is a drawing illustrating the ensuing process, which follows the process illustrated in FIG. 8.

FIG. 10 is a drawing illustrating the ensuing process, which follows the process illustrated in FIG. 9.

FIG. 11 is a drawing illustrating the ensuing process, which follows the process illustrated in FIG. 10.

FIG. 12 is a drawing illustrating the ensuing process, which follows the process illustrated in FIG. 11.

FIG. 13 is a drawing illustrating the ensuing process, which follows the process illustrated in FIG. 12.

FIG. 14 is a drawing illustrating the ensuing process, which follows the process illustrated in FIG. 13.

FIG. 15 is a partial perspective view of the micro channel manufactured according to the processes illustrated from FIG. 1 to FIG. 14.

FIG. 16 is a drawing illustrating the middle seed layer forming process according to the example of present invention.

FIG. 17 is a drawing illustrating the ensuing process, which follows the process illustrated in FIG. 16.

FIG. 18 is a drawing illustrating the ensuing process, which follows the process illustrated in FIG. 17.

FIG. 19 is a drawing illustrating the ensuing process, which follows the process illustrated in FIG. 18.

FIG. 20 is a drawing illustrating the ensuing process, which follows the process illustrated in FIG. 19.

FIG. 21 is a drawing illustrating the ensuing process, which follows the process illustrated in FIG. 20.

FIG. 22 is a drawing illustrating the ensuing process, which follows the process illustrated in FIG. 21.

FIG. 23 is a drawing illustrating the ensuing process, which follows the process illustrated in FIG. 22.

FIG. 24 is a drawing illustrating the ensuing process, which follows the process illustrated in FIG. 23.

FIG. 25 is a drawing illustrating the ensuing process, which follows the process illustrated in FIG. 24.

FIG. 26 is a cross sectional view of the complex micro structure manufactured according to the processes illustrated from FIG. 16 to FIG. 25.

FIG. 27 is a drawing illustrating the process for forming pattern with prescribed incline plane according to the other example of present invention.

FIG. 28 is a drawing illustrating the ensuing process, which follows the process illustrated in FIG. 27.

FIG. 29 is a drawing illustrating the ensuing process, which follows the process illustrated in FIG. 28.

FIG. 30 is a drawing illustrating the ensuing process, which follows the process illustrated in FIG. 29.

FIG. 31 is a drawing illustrating the ensuing process, which follows the process illustrated in FIG. 30.

FIG. 32 is a drawing illustrating the ensuing process, which follows the process illustrated in FIG. 31.

FIG. 33 is a drawing illustrating the ensuing process, which follows the process illustrated in FIG. 32.

FIG. 34 is a drawing illustrating the ensuing process, which follows the process illustrated in FIG. 33.

FIG. 35 is a drawing illustrating the ensuing process, which follows the process illustrated in FIG. 34.

FIG. 36 is a drawing illustrating the ensuing process, which follows the process illustrated in FIG. 35.

FIG. 37 is a drawing illustrating the ensuing process, which follows the process illustrated in FIG. 36.

FIG. 38 is a drawing illustrating the ensuing process, which follows the process illustrated in FIG. 37.

FIG. 39 is a drawing illustrating the ensuing process, which follows the process illustrated in FIG. 38.

FIG. 40 is a cross sectional view of the micro structure with side incline plane manufactured according to the processes illustrated from FIG. 27 to FIG. 39.

FIG. 41 is a follow chart illustrating the manufacturing process of for three-micro dimensional micro structure having high aspect ratio according to the present invention

### REFERENCE NUMERALS IN DRAWINGS

1: silicon substrate
2: seed layer
3,6,9,11,15,18,20: photosensitive coating layer
5,8,10,12,14,17,19,21,22: metal layer
13: micro channel
26: micro structure
27,28,29: middle seed layer
40: mask

### DETAILED DESCRIPTION OF PREFERRED EMBODIMENTS

The purpose of the present invention is achieved by providing the mass production method for three-dimensional micro structure having high aspect ratio, comprising the steps of: dividing the three-dimensional micro structure, which is to be manufactured, into prescribed numbers of imaginary layers (step A); forming a seed layer on a substrate (step B); forming a photosensitive material coating layer with prescribed thickness on said seed layer through coating photosensitive material (step C); forming a space for plating through patterning, said space corresponds to the shape of the divided layer of the micro structure which was divided in above step A (step D); forming a metal layer through filling up said space for plating with plating method (step E); flattening the upper surface of the said metal layer and the photosensitive material coating layer through grinding (step F); forming a photosensitive material coating layer with prescribed thickness on said upper surface flattened with grinding in step F, through coating photosensitive material (step H); forming a metal layers, which correspond to each divided layers in step A, by repeating the above steps from step D to step H, and depositing the formed metal layers (step I); and removing the substrate, photosensitive material coating and seed layer through etching after step I, and obtaining micro structure (step J).

In the above processes, there are cases when the step of forming middle seed layer on said upper surface flattened with grinding in step F should be further included between the step F and step H. In here, the said middle seed layer is the same material with the metal layer and thinner than said metal layer (step G).

In the above processes, in step A, it is preferred that the three-dimensional micro structure is divided horizontally.

In here, in step B, it is preferred that said substrate is made up of single crystal silicon, said seed layer is made up of conductive material, and said seed layer is formed on the substrate though any one method of sputtering, chemical vapor deposition (CVD) or evaporation.

In here, in step C and step F, it is preferred that said photosensitive material has large viscosity and the thickness of said photosensitive material coating layer is 200˜300 μm.

In here, in step D, it is preferred that any one light source of ultraviolet light, X-ray or laser is used.

In here, in step D of patterning, it is preferred that the amount of light exposed on the boundary area of photosensitive material, which is located between the exposed area and the unexposed area by mask, is regulated so that the side plane of the pattern, which is formed on said photosensitive material coating layer, forms incline plane.

In here, in step F, it is preferred that the step is performed through lapping or CMP.

In here, during the repeating process of step I, it is preferred that different kinds of metals are used as depositing metal layers in each plating process of step E.

The preferred embodiment is illustrated in the following detailed description referring to the accompanying drawings.

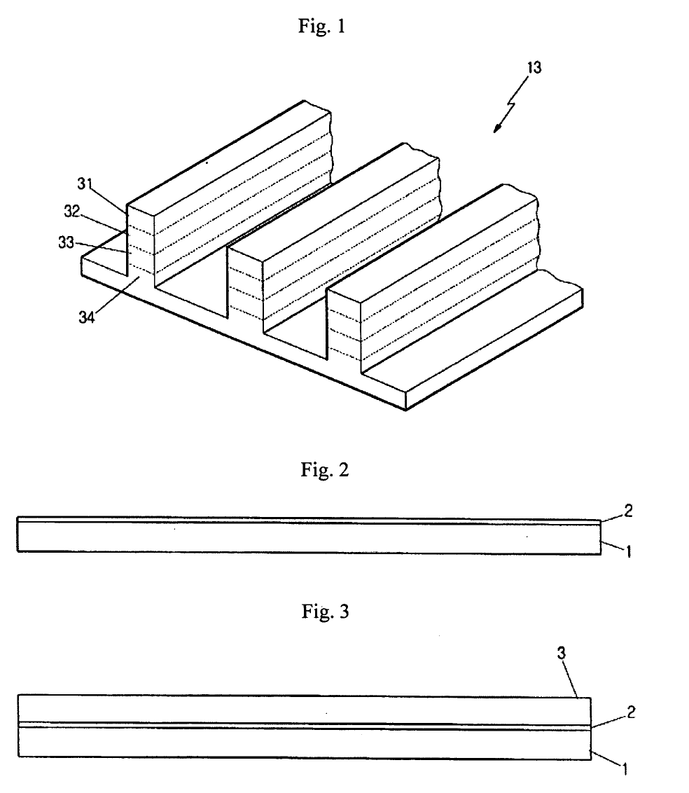

FIG. 1 is a drawing showing the partial perspective view of the macro channel.

In the first place, the characteristics of the present invention will be illustrated by applying the method according to the present invention to the manufacturing process of the micro channel shown in FIG. 1.

In the figures from FIG. 2 to FIG. 14 are illustrated the sequential manufacturing processes of the micro channel shown in FIG. 1, by applying the method according to the present invention. The broken lines from FIG. 9 to FIG. 13 are the imaginary lines that discriminate the plated metal layers of the present process with the plated metal layers of the previous process.

As illustrated as broken line in FIG. 1, micro channel 13 is divided into adequate number of imaginary layers. The thickness of the divided layers is about 100˜300 μm and it is not necessary that all the layers have the same thickness.

At first, seed layer 2 is formed on silicon substrate 1(FIG. 2). The seed layer is made up of conductive material, and the seed layer is formed on the substrate though any one material of sputtering, chemical vapor deposition (CVD) or evaporation. It is preferred that the material of the seed layer 2 is different from that of the metal layer or the middle seed layer, which is to be explained later.

Then, photosensitive coating layer 3 with prescribed thickness is formed on said seed layer through coating photosensitive material (FIG. 3). In here, the prescribed thickness denotes the thickness corresponding to the decided dividing thickness of the micro channel, which is to be manufactured. The coating process can be done with spin coater, and it is preferred that the SU-8 series photoresist (PR) is used as a photosensitive material, which has large viscosity. Usually, the SU-8 series photoresist (PR) is used as thick film type photoresist.

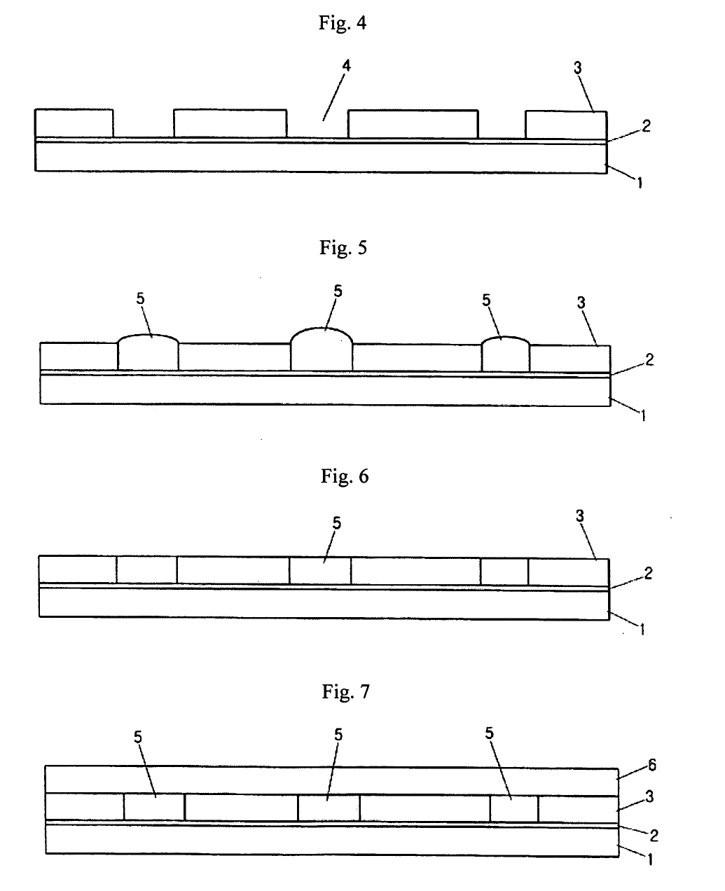

Then, a space 4 for plating is formed on the photosensitive material coating layer 3 through patterning, and the space 4 corresponds to the shape of the uppermost located divided layer 31 of the micro structure which was divided in FIG. 1(FIG. 4). In case of using negative type photoresist as SU-8, which is mentioned above, the area exposed to light remains. As the SU-8 shows high transmittancy to the ultraviolet series light sources, 200˜300 μm thickness of photosensitive material can be exposed to light to the intended depth, without employing expensive devices such as X-ray or excimer laser.

Then, a metal layer 5 is formed by filling up said space 4 formed on the photosensitive material with plating process (FIG. 5). As the seed layer 2 is conductive while the photosensitive material coating layer 3 is not conductive, the plating process is performed only in the photosensitive material removed space 4. The plating process is performed in the plating bath. And, for the prevention of pitting phenomenon, which prohibit the uniform plating because of the alien substances or the sub micron sized air bubbles, antipitting agent is added to the plating bath. The kind of metals, which are used in the plating process, are not limited and various metals with various physical property can be used according to the purpose of the micro structure.

Then, the protruded upper surface of the said metal layer, which was formed in the previous plating process and projected to the surface than the photosensitive material coating layer 3, is flattened through grinding (FIG. 6). The grinding process is performed through lapping or CMP (Chemical Mechanical Polishing). While lapping can remove large amount at a time, it leaves scratches on the surface. CMP, to the contrary, can remove small amount at a time but enhances the surface roughness. Accordingly, it is preferred to use both grinding methods.

Then, photosensitive material coating layer with prescribed thickness is formed on said upper surface flattened with grinding through coating photosensitive material (FIG. 7). This process is the same as the photosensitive material coating layer coating process illustrated in FIG. 3.

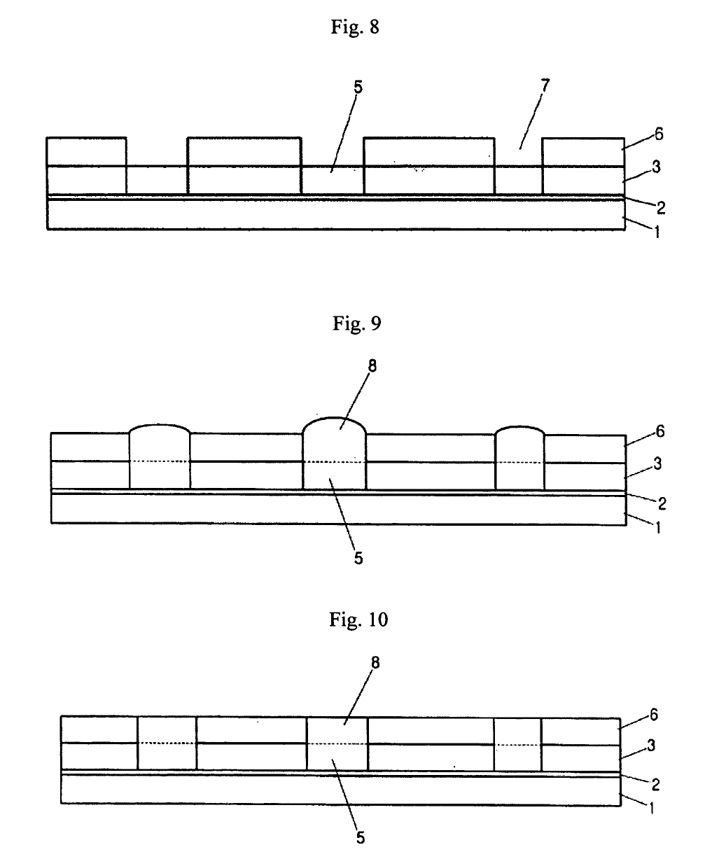

In FIG. 8, a space 7 for plating is formed through patterning, and the space 7 corresponds to the shape of the second layer 32 of the micro structure that was divided in FIG. 1. This process is the repetition of the process illustrated in FIG. 4. As an aligning method, the align mark (not illustrated), which was used in the process illustrated in FIG. 4, is used in this process.

In FIG. 9, a metal layer 8 is formed though filling up the space 7 with plating process. This process is the repetition of the process illustrated in FIG. 5.

In FIG. 10, the uneven surface of the plated metal layer is grinded with lapping or CMP. This process is the repetition of the process illustrated in FIG. 6.

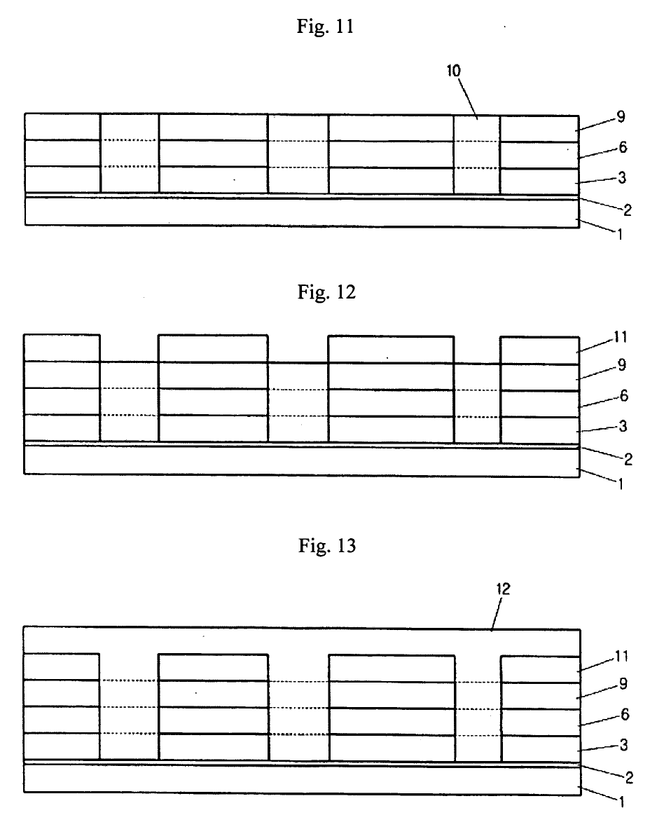

In FIG. 11, the metal layer corresponding to the third layer 33 in FIG. 1 is formed through repeating the processes illustrated from FIG. 7 to FIG. 10. In the metal layer forming process, illustrated in FIG. 5, of the repeating processes, different kind of metal can be used so that each material of the metal layers are different from one another.

In FIG. 12, after the additional photosensitive material coating layer 11 is formed, and the space corresponding to the fourth metal layer 34 of the FIG. 1 is formed through patterning.

In FIG. 13, the metal layer 12 corresponding to the fourth metal layer 34 of the FIG. 1 is formed through plating and grinding.

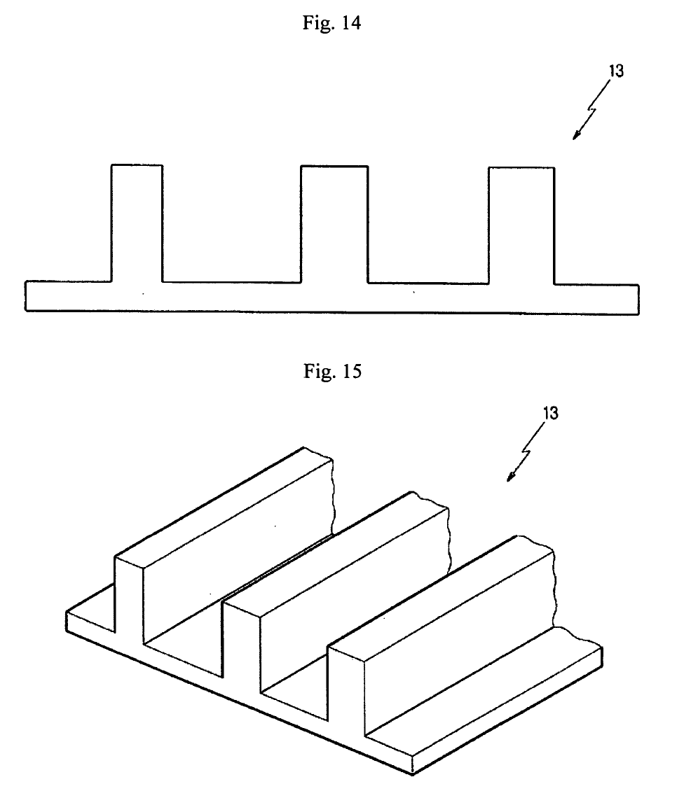

In FIG. 14, the substrate, photosensitive material coating and seed layer are removed through etching. And, finally, by rotating the product 180°, the micro channel with metal material and the shape illustrated in FIG. 1, is produced by the method represented in the present invention.

The silicon substrate is removed in water bath added with etchant such as KOH, TMAH (Tetra Methyl Ammonium Hydroxides) and heated at a fixed temperature for a fixed time. The seed layer is removed by the etchant corresponding to the material of the seed layer. Different kinds of material are used for the seed layer and the micro channel, so that the etchant remove the material selectively. In case of using copper as seed layer, HNO₃:H₂O=2:1 solution is used for the removal of copper. The photosensitive material is removed with the remover for the photosensitive material. In case of SU-8, exclusive remover called “Nano remover PG” is used. In the silicon wet etching process, it is also possible that KOH or TMAH are used to remove the silicon and photosensitive material at the same time.

FIG. 15 is a partial perspective view of the micro channel manufactured according to the processes illustrated till now.

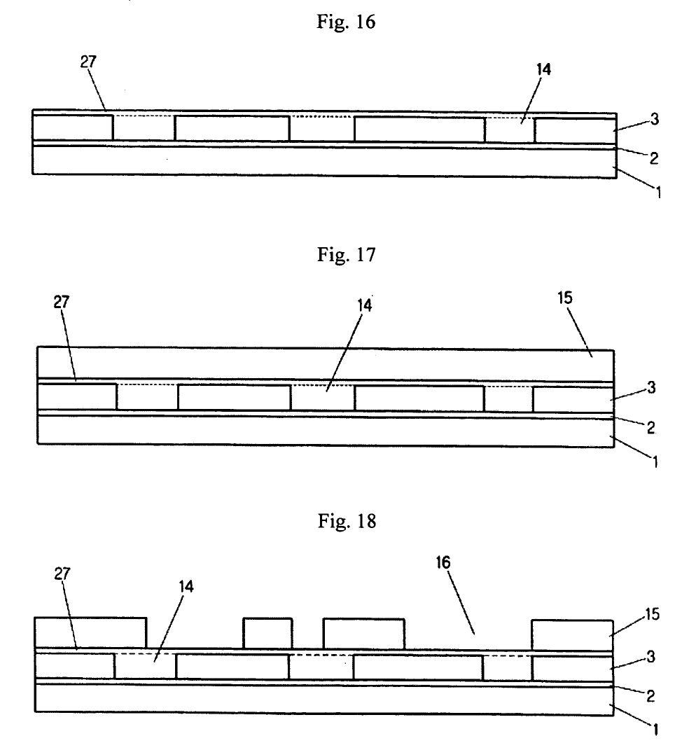

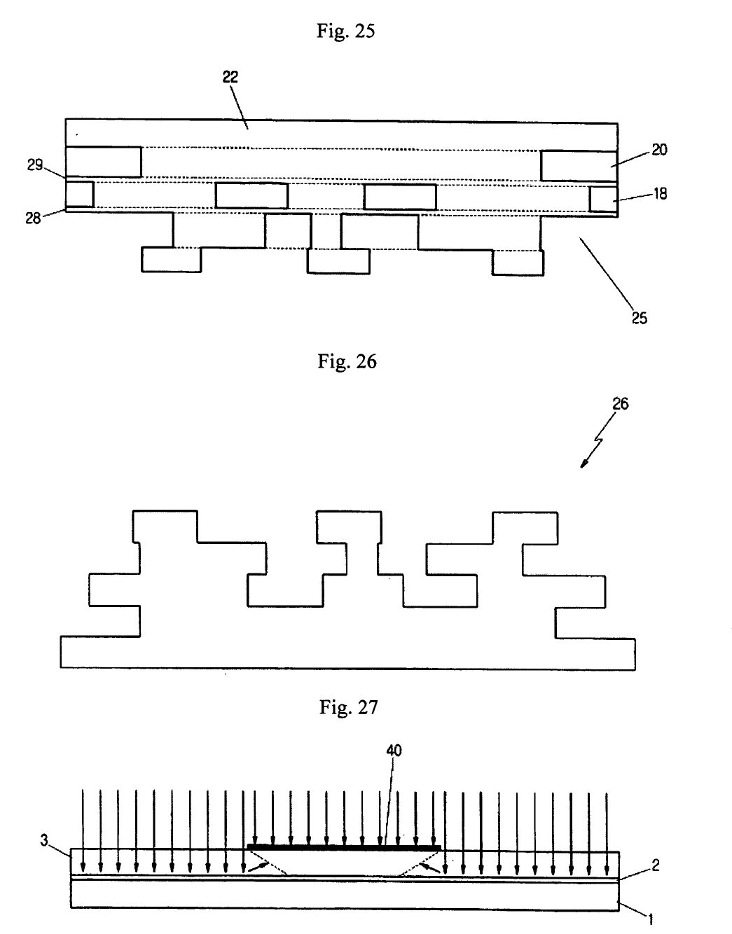

In the FIG. 16 through FIG. 26 are illustrated the manufacturing processes for the complex shaped micro structure by using the method according to the present invention, which was intended to show that the present invention is suitable for the complicated structure. The processes to be illustrated in the following, unlike the processes illustrated from FIG. 1 to FIG. 15, can be applied to the micro structures where the adjacent layers are not directly connected or the width of the connected area is small.

The processes illustrated from FIG. 1 to FIG. 6 are in common with the other example of the present invention. That is: dividing the three-dimensional micro structure, which is to be manufactured, into prescribed numbers of imaginary layers; forming a seed layer on a substrate; forming a photosensitive material coating layer on said seed layer; forming a space for plating through patterning, said space corresponds to the shape of the divided layer of the micro structure which was imaginary divided; forming a metal layer through filling up said space with plating method; and flattening the protruded upper surface of the said metal layer through grinding.

Then, as illustrated in FIG. 16, middle seed layer 27 with the same material with the plated metal is uniformly deposited on the flattened surface. The deposition is performed though any one method of sputtering, chemical vapor deposition (CVD) or evaporation.

Then, a photosensitive material coating layer 15 with prescribed thickness is formed on the uniformly formed middle seed layer 27 through coating photosensitive material (FIG. 17). This process is the same as the photosensitive material coating process illustrated in FIG. 3.

In FIG. 18, a space 16 for plating is formed through patterning on the photosensitive material coating layer, which was illustrated in FIG. 17, and the space 16 corresponds to the shape of the second layer of the micro structure which is to be manufactured. This process is analogous to the process illustrated in FIG. 4 except the shape of the pattern, and the align mark, which was used in the process illustrated in FIG. 4, is used for the exact alignment.

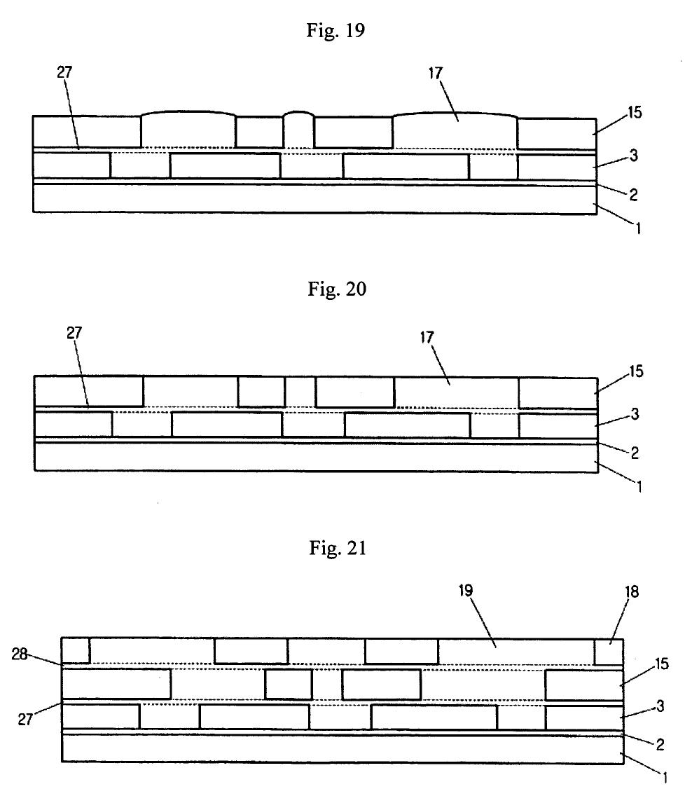

In FIG. 19, a metal layer 17 is formed though filling up the space 16, which was formed in the process illustrated in FIG. 18, with plating process. This process is the repetition of the process illustrated in FIG. 5.

In FIG. 20, the uneven surface of the plated metal layer, which was formed in the process illustrated in FIG. 19, is grinded with lapping or CMP. This process is the repetition of the process illustrated in FIG. 6.

In FIG. 21, the middle seed layer 28, photosensitive material coating layer 18 and the metal layer 19 are formed through repeating the processes illustrated from FIG. 16 to FIG. 20. In the metal layer forming process, illustrated in FIG. 5, of the repeating processes, different kind of metal can be used so that each material of the metal layers are different from one another.

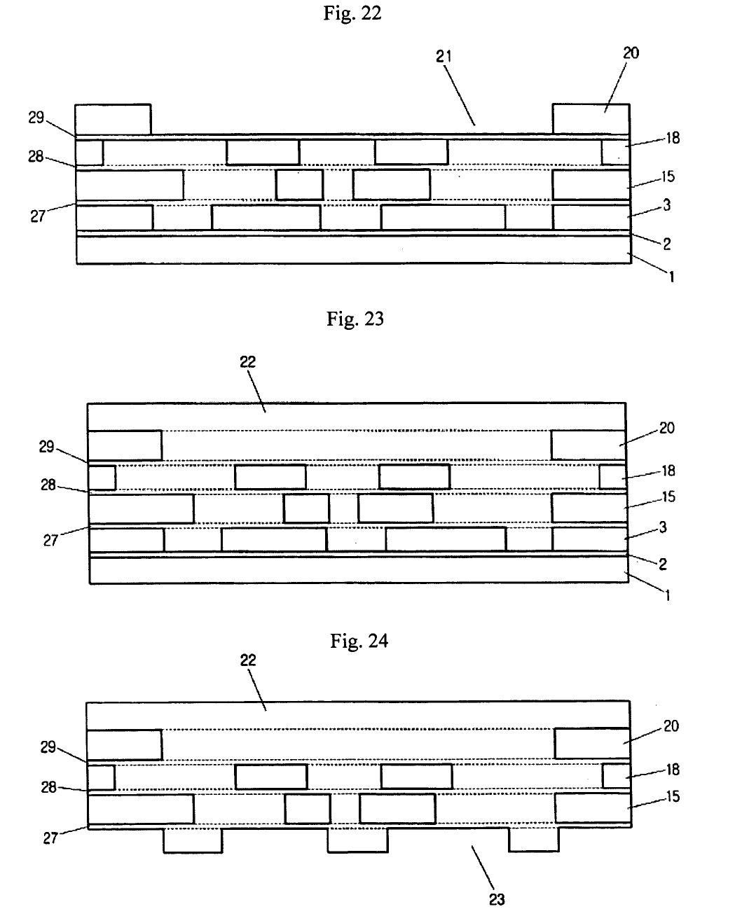

In FIG. 22, after the additional photosensitive material coating layer 20 is formed, and the space 21 corresponding to the shape of the next metal layer is formed through patterning.

In FIG. 23, the metal layer 22 is formed through filling up the space 21 with plating and following grinding process is performed.

In FIG. 24 is illustrated state, where the substrate 1, seed layer 2 and the lowest photosensitive material coating layer are removed.

In FIG. 24, the silicon substrate, seed layer and the photosensitive material are removed.

As the same method illustrated in FIG. 14, the silicon substrate is removed by the etchant such as KOH, TMAH (Tetra Methyl Ammonium Hydroxides), the seed layer is removed by the etchant corresponding to the material of the seed layer, and the photosensitive material is removed by the exclusive. And in the silicon wet etching process, it is also possible that KOH or TMAH is used to remove the silicon and photosensitive material at the same time.

Unlike the processes illustrated above, in this preferred embodiment, further layer of middle seed layer with the same material with the metal layer but with different thickness, is formed. That is, while the metal layers are formed at the thickness of 200˜300 μm, the middle seed layers are formed at the thickness of about 5000 Å.

The middle seed layers are helpful in case where the metal layers are not connected continuously or the width of the connecting area is small. When the final plating process for the intended shape has finished, the middle seed layers can be removed with a short period of seconds of dipping in corresponding metal etchant without any harm to the metal layers.

With the state illustrated in FIG. 24, the middle seed layers are removed by dipping in the etchant solution in a few seconds. In FIG. 24 is illustrated the photosensitive material coating layer removing process using the remover for photosensitive material, KOH or TMAH. Unlike the processes illustrated above, the photosensitive material coating layer and the middle seed layer are removed sequentially one by one.

The micro structure with the cross sectional view illustrated in FIG. 26 can be obtained with the processes explained till now.

Till now, the manufacturing process for the micro structure with regular cross sectional shape has been illustrated. But, the method according to the present invention can be applied to the manufacturing of sphere shaped structure, H-beam shaped structure or dumbbell shaped structure. And, also, the method according to the present invention can be applied to the manufacturing of three-dimensional micro structure having high aspect ratio.

Meanwhile, in manufacturing the micro structure through dividing and depositing with the method according to the present invention, there may be cases where the side plane of the layers are not vertical but inclined. In the following is illustrated another preferred embodiment of the manufacturing method for the micro structure with inclined side wall.

From FIG. 27 to FIG. 40 are illustrated the manufacturing method for the micro structure with inclined side wall. In this processes, the same processes with the previous preferred embodiments are employed except for the process of forming inclined side plane through patterning process with the regulation of the amount of exposed light. Accordingly, the common processes are omitted.

The processes illustrated from FIG. 1 to FIG. 3 are in common with the present preferred embodiment. That is, the object is divided with imaginary layers. And, seed layer 2 is formed on silicon substrate 2, and then, photosensitive material coating layer 3 is formed on the seed layer 2.

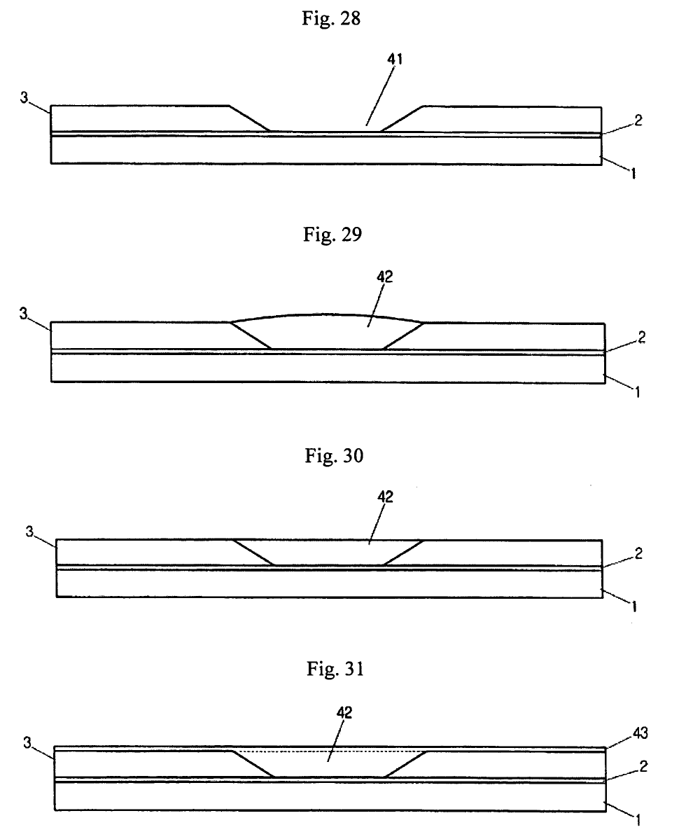

As illustrated in FIG. 27, in the patterning process of the photosensitive material coating layer 3, the expose energy is increased to a certain degree. With the increased expose energy the photosensitive material coating layer under the mask 40 can be exposed to light. That is, when the photosensitive material coating layer is overexposed, the area under the mask 40 can be exposed to light as indicated by arrow. The result of the above patterning process is illustrated in FIG. 28.

In case of using negative type photoresist as SU-8 series, the area exposed to light remains and the unexposed area is removed. Accordingly, the unexposed area under the mask 40 is removed. In the lower portion of the photosensitive material coating layer, the amount of exposed light become small and the removed area reduces. With such phenomenon, space 41 with inclined plane can be formed on the photosensitive material coating layer 3.

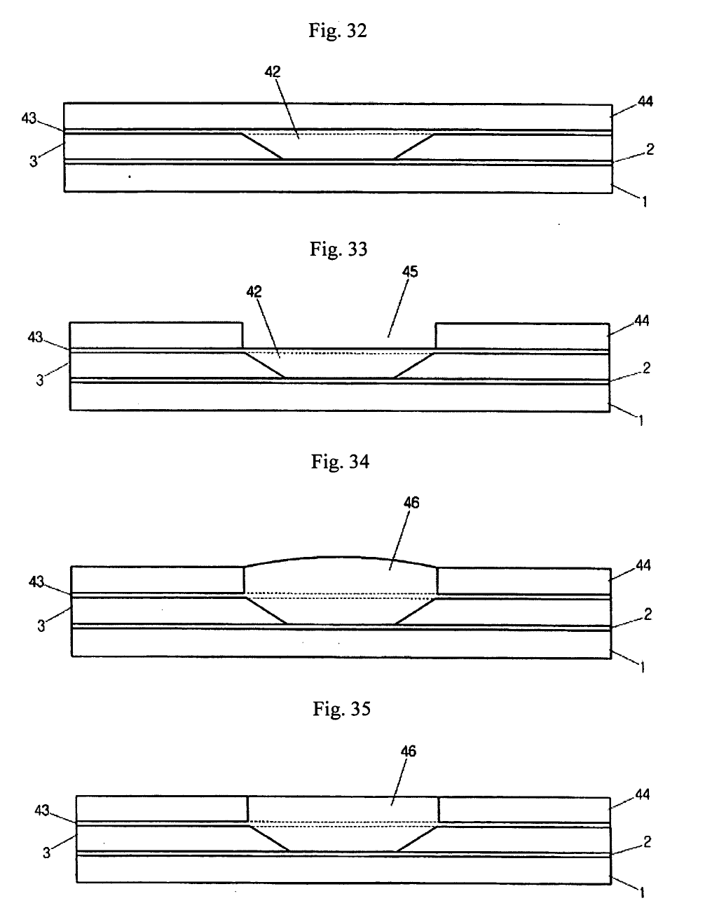

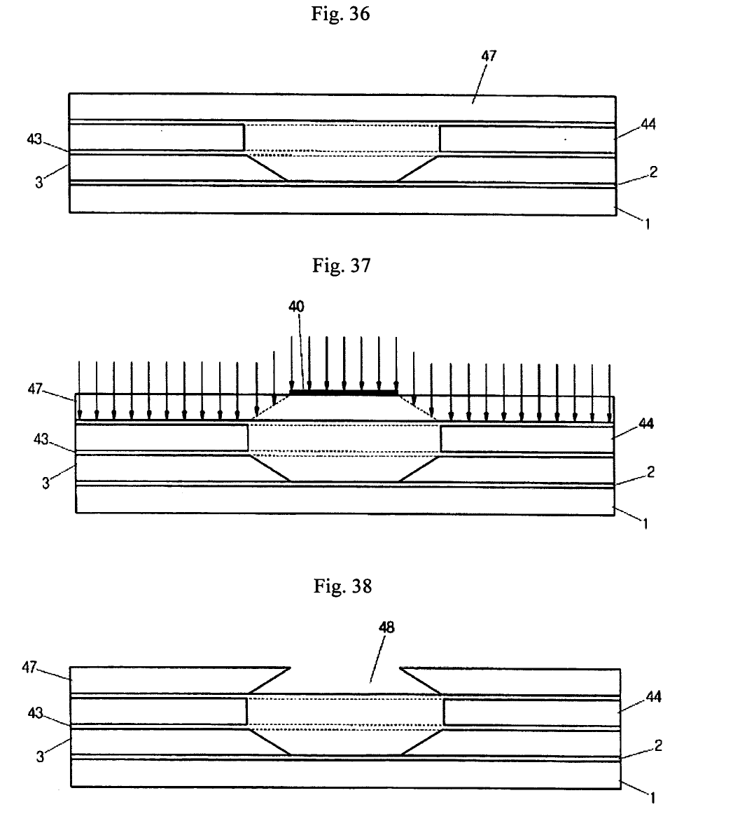

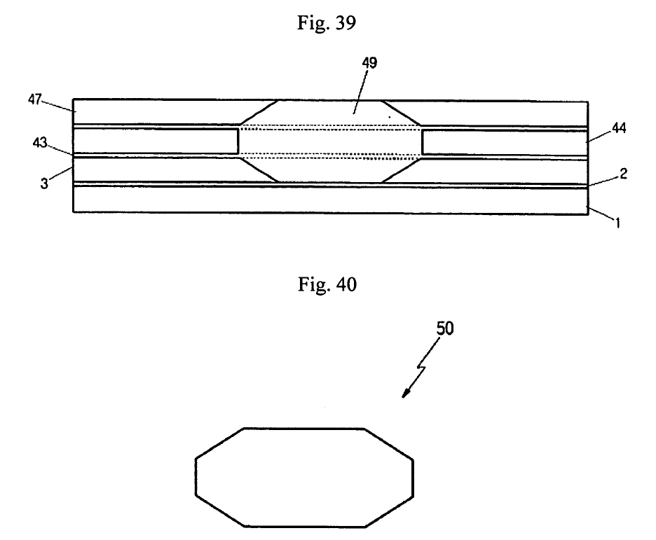

A metal layer 42 is formed though filling up said space, formed in the process of FIG. 28, with plating method (FIG. 29). The projected surface is flattened with grinding as illustrated in the above examples (FIG. 30). Middle seed layer 43 is formed on the grinded surface (FIG. 31). As illustrated above, it is preferred that same kind of material with the plated metal is used. Photosensitive material coating layer 44 is formed on the said middle seed layer 43(FIG. 32). A space 45 with vertical side plane is formed through patterning (FIG. 33). A metal layer 46 is formed though filling up said space 45 with plating method (FIG. 34). The projected surface is flattened with grinding (FIG. 35), and photosensitive material coating layer 47 is formed on the said middle seed layer 47 (FIG. 36). Light, with the energy level below a certain degree, is exposed in a way that the exposed depth becomes shallower as it approached the area adjacent to the mask 40. With the regulation of the depth of exposure to light in the area near the mask 40, the space 48 with the inclined side plane, as illustrated in FIG. 38, can be obtained. A metal layer 49 is formed though filling up said space 48 with plating method (FIG. 39). In here, after the grinding process, the silicon layer 1, seed layer 2, photosensitive material coating layer 3, 44,47 and middle seed layer 43 undergo etching process, and finally the micro structure, as illustrated in FIG. 40, can be obtained.

By applying the regulating method of the exposure energy, as illustrated above, the structure with inclined side plane can be manufactured easily.

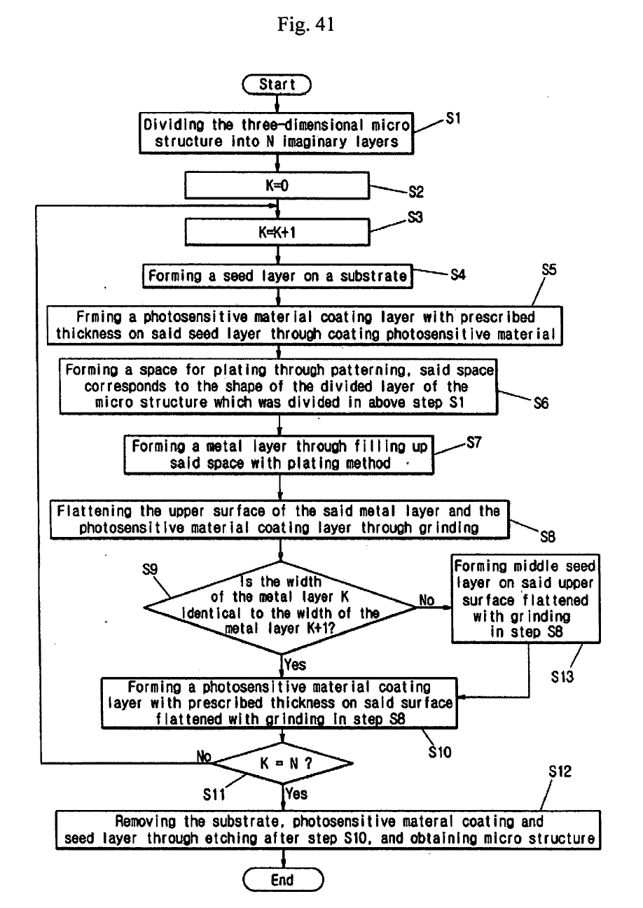

In FIG. 41 is shown the flowchart that illustrates the mass production method for three-dimensional micro structure having high aspect ratio according to the present invention.

As illustrated in FIG. 41, the mass production method for three-dimensional micro structure having high aspect ratio is comprising the steps of: dividing the micro structure, which is to be manufactured, into N imaginary layers (S1); setting the positive integral number K into 0 (S2); storing the new value of K by adding 1 to the previous value of K (S3); forming seed layer on the substrate (S4); forming a photosensitive material coating layer with prescribed thickness on said seed layer through coating photosensitive material (S5); forming a space for metal layer through patterning (S6); forming a metal layer through plating (S7); grinding the upper surface of the said metal layer and the photosensitive material coating layer (S8); identifying the differences of the width or the position of the metal layer K and the metal layer K+1 (S9); forming a middle seed layer on the grinded surface with plating, in case the differences of the width or the position of the metal layer K and the metal layer K+1 are detected (S13); forming a photosensitive material coating layer on the grinded surface (S10); confirming whether K is equal to N, and if K and N are different, returning to the above step (S3) and executing the following steps (S11); and, if K is equal to N, removing the substrate, photosensitive material coating and seed layer through etching and obtaining micro structure (S12).

As illustrated above, in the present invention, the manufacturing of the three-dimensional micro structure having high aspect ratio is possible, which was impossible with the prior art of MEMS or LIGA.

Especially, micro structure with complex shape can be obtained through dividing into layers and depositing the layers. Micro structure with any shape can be obtained with the method according to the present invention.

The forgoing embodiment is merely exemplary and is not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

1. A mass production method for three-dimensional micro structure having high aspect ratio, comprising the steps of:
dividing the three-dimensional micro structure, which is to be manufactured, into prescribed numbers of imaginary layers (step A);
forming a seed layer on a substrate (step B);
forming a photosensitive material coating layer with prescribed thickness on said seed layer through coating photosensitive material (step C);
forming a space for plating through patterning, said space corresponds to the shape of the divided layer of the micro structure which was divided in above step A (step D);
forming a metal layer through filling up said space for plating with plating method (step E);
flattening the upper surface of the said metal layer and the photosensitive material coating layer through grinding (step F);
forming a photosensitive material coating layer with prescribed thickness on said upper surface flattened with grinding in step F, through coating photosensitive material (step H);
forming a metal layers, which correspond to each divided layers in step A, by repeating the above steps from step D to step H, and depositing the formed metal layers (step I); and
removing the substrate, photosensitive material coating and seed layer through etching after step I, and obtaining micro structure (step J).

2. A mass production method for three-dimensional micro structure having high aspect ratio according to claim 1, wherein, the step of forming middle seed layer on said upper surface flattened with grinding in step F is included between the step F and step H, and said middle seed layer is thinner than said metal layer (step G);

3. A mass production method for three-dimensional micro structure having high aspect ratio according to claim 1, wherein, in step A, the three-dimensional micro structure is divided horizontally.

4. A mass production method for three-dimensional micro structure having high aspect ratio according to claim 1, wherein, in step B, said substrate is made up of single crystal silicon, said seed layer is made up of conductive material, and said seed layer is formed on the substrate though any one method of sputtering, chemical vapor deposition or evaporation.

5. A mass production method for three-dimensional micro structure having high aspect ratio according to claim 1, wherein, in step C and step F, said photosensitive material has large viscosity and the thickness of said photosensitive material coating layer is 200˜300 μm.

6. A mass production method for three-dimensional micro structure having high aspect ratio according to claim 1, wherein, in step D, any one light source of ultraviolet light, X-ray or laser is used.

7. A mass production method for three-dimensional micro structure having high aspect ratio according to claim 1, wherein, in step D of patterning, the amount of light exposed on the boundary area of photosensitive material, which is located between the exposed area and the unexposed area by mask, is regulated so that the side plane of the pattern, which is formed on said photosensitive material coating layer, forms incline plane.

8. A mass production method for three-dimensional micro structure having high aspect ratio according to claim 1, wherein, in step F, the step is performed through lapping or CMP.

9. A mass production method for three-dimensional micro structure having high aspect ratio according to claim 1, wherein, during the repeating process of step I, different kinds of metals are used as depositing metal layers in each plating process of step E.
